(19) United States
(12) Patent Application Publication
(10) Pub. No.: US 2009/0130836 A1
(43) Pub. Date: May 21, 2009

(54) METHOD OF FABRICATING FLASH CELL

(76) Inventor: Jong-Won Sun, Golseong-gun (KR)

Correspondence Address: SHERR & VAUGHN, PLLC, 620 HERNDON PARKWAY, SUITE 200, HERNDON, VA, 20170, US

(21) Appl. No.: 12/212,685

(22) Filed: Sep. 18, 2008

(30) Foreign Application Priority Data
Nov. 16, 2007 (KR) 10-2007-0117284

(51) Int. Cl. H01L 21/3205

(52) U.S. Cl. 438/594; 257/E21.294

(57) ABSTRACT

A method of fabricating a flash cell of a semiconductor device includes depositing a damage-prevention film on and/or over a hard mask pattern to prevent damage to an ONO film of a gate pattern when removing the hard mask using a vapor process chamber (VPC) process.

The present application claims priority under 35 U.S.C. §119 to Korean Patent Application No. 10-2007-0117284 (filed on Nov. 16, 2007), which is hereby incorporated by reference in its entirety.

### BACKGROUND

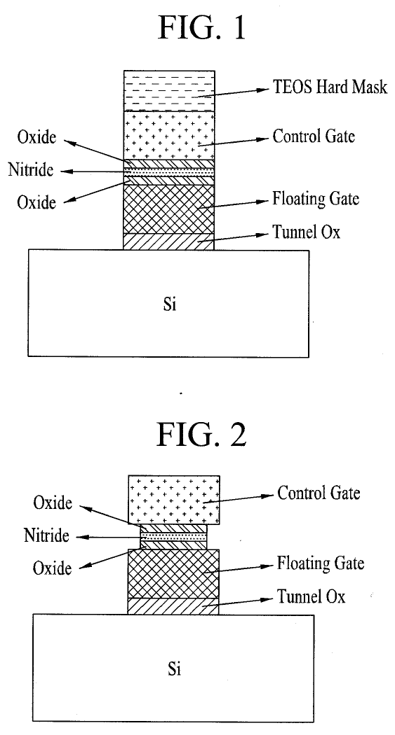

As illustrated in example FIG. 1, a flash cell may include tunnel oxide layer formed on and/or over a silicon substrate. A floating gate is formed on and/or over the tunnel oxide layer and a dielectric film having an ONO (oxide/nitride/oxide) structure may be formed on and/or over the floating gate. A control gate is then formed on and/or over the dielectric layer. A hard mask is formed on and/or over the control gate and serves to protect the control gate poly in the flash cell.

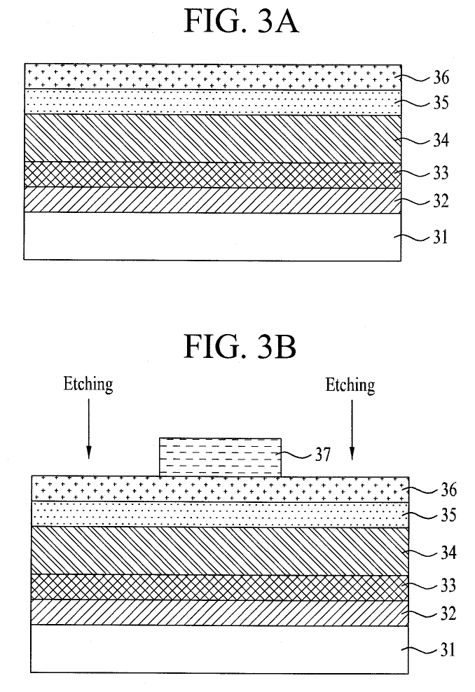

As illustrated in example FIG. 2, damage to the ONO film of the flash cell due to the hard mask. A tetra ethyl ortho silicate (TEOS), silicon oxide (SiO₂) or a nitride (Si₃N₄) may be used as the hard mask. The ONO film is generally damaged in a range between approximately 150 to 200 Å during the etching process to form the gate pattern. When the nitride is used as the hard mask, however, a nitride of the ONO film is severely damaged as illustrated in example FIG. 2. Even when the TEOS is used as the hard mask, the ONO is also damaged, and therefore, a coupling ratio decreases at the time of voltage (1V) application, with the result that gate voltage decreases, which deteriorates device properties.

### SUMMARY

Embodiments relate to a semiconductor device, and more particularly, to a method of fabricating a flash cell of the semiconductor device.

Embodiments relate to a method of fabricating a flash cell that minimizes damage to an ONO film during the removal of a hard mask.

Embodiments relate to a method of fabricating a flash cell of the semiconductor device that may include at least one of the following steps: sequentially forming a tunnel oxide film, a floating gate, an oxide/nitride/oxide (ONO) film, a control gate, and a hard mask on and/or over a semiconductor substrate; and then depositing a damage-prevention film to prevent the damage to the ONO film on and/or over the entire surface of the semiconductor substrate including the hard mask; and then removing the hard mask using a vapor process chamber (VPC) process.

Embodiments relate to a method of fabricating a flash cell of a semiconductor device that may include at least one of the following steps: forming a gate pattern including a tunnel oxide film, a floating gate, an oxide/nitride/oxide (ONO) film and a control gate over a semiconductor substrate; and then forming a hard mask pattern over the gate pattern; and then forming a protective film over the entire surface of the semiconductor substrate including the gate pattern and the hard mask; and then removing at least the hard mask by performing a vapor process chamber (VPC) process.

Embodiments relate to a method of fabricating a flash cell that may include at least one of the following steps: forming a gate pattern over a semiconductor substrate; and then forming a hard mask pattern over and contacting the uppermost surface of the gate pattern; and then forming a silicon film as a protective film over the entire surface of the semiconductor substrate such that the silicon film is formed over the uppermost surface of the hard mask pattern and also over sidewalls of the hard mask pattern and the gate pattern; and then removing the silicon film and the hard mask.

Embodiments relate to a method that may include at least one of the following steps: forming a gate pattern over a semiconductor substrate; and then forming a hard mask pattern over the gate pattern; and then forming one of silicon oxide (SiO₂) and silicon nitride (Si₃N₄) as a protective film over the uppermost surface of the semiconductor substrate and the hard mask pattern and also over sidewalls of the hard mask pattern and the gate pattern; and then removing the hard mask.

In accordance with embodiments, the hard mask pattern may be formed of a tetra ethyl ortho silicate (TEOS) or a nitride. The damage-prevention film may be formed of one of SiO₂ and Si₃N₄ and may have a thickness in a range between approximately 100 to 200 Å. The step of depositing the damage-prevention film may be carried out using one of a medium temperature oxide (MTO) process and a low temperature oxide (LTO) process. When a MTO process is used, the damage-prevention film may be deposited using a silane gas at a temperature in a range between approximately 600 to 700° C. When an LTO process is used, the damage-prevention film may be deposited using a DCS gas at a temperature in a range between approximately 300 to 500° C.

### DRAWINGS

Example FIGS. 1 and 2 illustrate a flash cell and resultant damage to an ONO film of the flash cell.

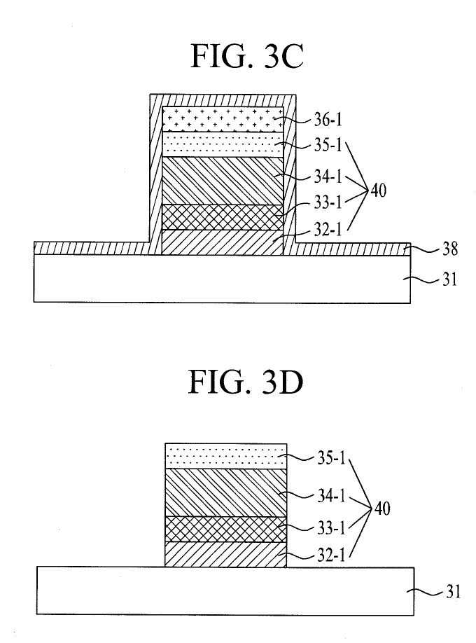

Example FIGS. 3A to 3D illustrate a sequence of views of a method of fabricating a flash cell of a semiconductor device in accordance with embodiments.

### DESCRIPTION

Reference will now be made in detail to embodiments, examples of which are illustrated in the accompanying drawings. Wherever possible, the same reference numbers will be used throughout the drawings to refer to the same or like parts.

As illustrated in example FIG. 3A, tunnel oxide film 32 is formed on and/or over semiconductor substrate 31 by a growth process. Floating gate poly 33 may then be formed on and/or over tunnel oxide film 32 by deposition using low pressure chemical vapor deposition (LPCVD). Subsequently, ONO film 34 including a first oxide film, a nitride film and a second oxide film are sequentially deposited on and/or over floating gate poly 33 using LPCVD. Control gate poly 35 may then be formed on and/or over ONO film 34 using LPCVD. Subsequently, hard mask 36 to prevent damage to control gate poly 35 is formed on and/or over control gate poly 35. One of a TEOS film and a nitride film may be used as hard mask 36.

As illustrated in example FIG. 3B, a photoresist may then be applied to hard mask 36 and then patterned using an exposing and developing process to form photoresist pattern 37. In accordance with embodiments, hard mask 36 is then etched to form a hard mask pattern using photoresist pattern 37 as an etching mask. Subsequently, the residual portion of photoresist pattern 37 is removed. Alternatively, photoresist pattern 37 may not be removed. Control gate poly 35, ONO film 34, floating gate poly 33 and tunnel oxide film 32 may then be sequentially etched using the hard mask pattern as an etch barrier. In accordance with embodiments, hard mask 36, control gate poly 35, ONO film 34, floating gate poly 33 and tunnel oxide film 32 may be sequentially etched using photoresist pattern 37 as an etching mask, and then the residual portion of photoresist pattern 37 is removed.

As illustrated in example FIG. 3C, gate pattern 40 is formed on and/or over semiconductor substrate 31 as a result of the etching process. Damage-prevention film 38 for preventing damage to ONO film 34 is deposited on and/or over the entire surface of semiconductor substrate 31 including hard mask pattern 36-1 and gate pattern 40 (i.e., control gate poly pattern 35-1, ONO film pattern 34-1, floating gate poly pattern 33-1 and tunnel oxide film pattern 32-1) and sidewalls thereof. Meaning, damage-prevention film 38 may be deposited to cover the uppermost surface and sidewalls of the gate pattern. Damage-prevention film 38 may be deposited on and/or over surface of semiconductor substrate 31 including gate pattern 40. Specifically, damage-prevention film 38 may be formed on and/or over the uppermost surface of hard mask pattern 36-1 and sidewalls of gate pattern 40. Damage-prevention film 38 in accordance with embodiments may be formed of one of SiO₂ and Si₃N₄ having a thickness in a range between approximately 100 to 200 Å.

Without protecting the ONO film during the etching process to form the gate pattern, damage to the ONO film may result in a reduction of thickness in a range between approximately 150 to 200 Å. For this reason, it is preferred for damage-prevention film 38 to have a thickness in a range between approximately 150 to 200 Å. Also, damage-prevention film 38 is formed not using methods such as oxidation, RTP, TEOS, and HTO, but using one of a medium temperature oxide (MTO) process and a low temperature oxide (LTO) process in order to minimize thermal budget and maximize the quality of SiO₂ or Si₃N₄ of damage-prevention film 38. When MTO processing is used, damage-prevention film 38 is deposited on and/or over hard mask 36 using silane gas at a temperature in a range between approximately 600 to 700° C. When LTO processing is used, damage-prevention film 38 is deposited on and/or over hard mask 36 using dichlorosilane (DCS) gas at a temperature in a range between approximately 300 to 500° C.

As illustrated in example FIG. 3D, a vapor process chamber (VPC) process using HF vapor is carried out to remove damage-prevention film 38 and hard mask 36. At this time, damage-prevention film 38 protects the sidewalls of gate pattern 40. Accordingly, the method of fabricating the flash cell in accordance with embodiments minimizes damage to an ONO film during removal of a hard mask, thereby stably securing gate application voltage without loss.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of fabricating a flash cell of a semiconductor device comprising:
forming a gate pattern including a tunnel oxide film, a floating gate, an oxide/nitride/oxide (ONO) film and a control gate over a semiconductor substrate; and then
forming a hard mask pattern over the gate pattern; and then
forming a protective film over the entire surface of the semiconductor substrate including the gate pattern and the hard mask; and then
removing at least the hard mask by performing a vapor process chamber (VPC) process.

2. The method of claim 1, wherein the hard mask pattern is formed of tetra ethyl ortho silicate (TEOS).

3. The method of claim 1, wherein the hard mask pattern is formed of a nitride.

4. The method of claim 1, wherein the protective film is formed of a silicon oxide (SiO₂) film.

5. The method of claim 4, wherein the silicon oxide (SiO₂) film has a thickness in a range between approximately 100 to 200 Å.

6. The method of claim 1, wherein the protective film comprises a silicon nitride (Si₃N₄) film.

7. The method of claim 6, wherein the silicon nitride (Si₃N₄) film has a thickness in a range between approximately 100 to 200 Å.

8. The method of claim 1, wherein the protective film has a thickness in a range between approximately 100 to 200 Å.

9. The method of claim 1, wherein forming the protective film is carried out by performing a medium temperature oxide (MTO) process.

10. The method of claim 9, wherein performing the MTO process comprises depositing the protective film using silane gas at a temperature in a range between approximately 600 to 700° C.

11. The method of claim 1, wherein forming the protective film is carried out by performing a low temperature oxide (LTO) process.

12. The method of claim 11, wherein performing the LTO process comprises depositing the protective film using dichlorosilane (DCS) gas at a temperature in a range between approximately 300 to 500° C.

13. The method of claim 1, wherein removing at least the hard mask includes performing the vapor process chamber (VPC) process using hydrogen fluoride (HF) vapor.

14. The method of claim 1, wherein forming the protective film comprises depositing the protective film over the uppermost surface of the hard mask pattern and sidewalls of the hard mask pattern and the gate pattern.

15. The method of claim 1, wherein forming the gate pattern comprises:
sequentially forming the tunnel oxide film, the floating gate poly, the ONO film and the control gate poly over the semiconductor substrate; and then
forming a hard mask film over the uppermost surface of the control gate poly; and then
forming a photoresist pattern over the hard mask film; and then
etching the hard mask film using the photoresist pattern as an etching mask to form the hard mask pattern; and then
removing the photoresist pattern; and then
sequentially etching the control gate poly, the ONO film, the floating gate poly, and the tunnel oxide film using the hard mask pattern as a mask.

16. A method of fabricating a flash cell comprising:
forming a gate pattern over a semiconductor substrate; and then
forming a hard mask pattern over and contacting the uppermost surface of the gate pattern; and then
forming a silicon film as a protective film over the entire surface of the semiconductor substrate such that the silicon film is formed over the uppermost surface of the hard mask pattern and also over sidewalls of the hard mask pattern and the gate pattern; and then
removing the silicon film and the hard mask.

17. The method of claim 16, wherein forming the silicon film comprises depositing silicon oxide (SiO₂) having a thickness in a range between approximately 100 to 200 Å by performing a medium temperature oxide (MTO) process using silane gas at a temperature in a range between approximately 600 to 700° C.

18. The method of claim 16, wherein forming the silicon film comprises depositing silicon nitride (Si₃N₄) having a thickness in a range between approximately 100 to 200 Å by performing a low temperature oxide (LTO) process using dichlorosilane (DCS) gas at a temperature in a range between approximately 300 to 500° C.

19. The method of claim 16, wherein the hard mask pattern comprises one of a tetra ethyl ortho silicate (TEOS) and a nitride film.

20. A method comprising:
forming a gate pattern over a semiconductor substrate; and then
forming a hard mask pattern over the gate pattern; and then
forming one of silicon oxide (SiO₂) and silicon nitride (Si₃N₄) as a protective film over the uppermost surface of the semiconductor substrate and the hard mask pattern and also over sidewalls of the hard mask pattern and the gate pattern; and then
removing the hard mask.
